(19) United States
(12) Patent Application Publication
(10) Pub. No.: US 2026/0311960 A1
(43) Pub. Date: Oct. 8, 2026

(54) SYSTEMS AND METHODS FOR OPTIMIZING SCANNING OF SAMPLES IN INSPECTION SYSTEMS

(71) Applicant: ASML Netherlands B.V., Veldhoven (NL)

(72) Inventors: Te-Yu CHEN, San Jose, CA (US); Johannes Catharinus Hubertus MULKENS, Valkenswaard (NL)

(73) Assignee: ASML Netherlands B.V., Veldhoven (NL)

(21) Appl. No.: 19/481,311

(22) PCT Filed: Apr. 17, 2024
(86) PCT No.: PCT/EP2024/060454

§ 371 Date: Nov. 4, 2025

Related U.S. Application Data
(60) Provisional application No. 63/464,501, filed on May 5, 2023.

(51) Int. Cl. H01J 37/26; H01J 37/28

(52) U.S. Cl. CPC H01J 37/265; H01J 37/28; H01J 2237/221; H01J 2237/24495; H01J 2237/24592

(57) ABSTRACT

Systems and methods for optimizing scanning of a sample. Systems and methods may include providing a plurality of charged particle beams for scanning a first sample; identifying one or more failed charged particle beams of the plurality of charged particle beams; identifying one or more functional charged particle beams of the plurality of charged particle beams that scan the first sample; generating a beam map based on the identified one or more failed charged particle beams and the identified one or more functional charged particle beams, wherein the generated beam map excludes the identified one or more failed charged particle beams; and developing a scanning strategy based on the generated beam map for scanning the first sample or a second sample.

### CROSS-REFERENCE TO RELATED APPLICATIONS

This application claims priority of U.S. application 63/464,501 which was filed on May 5, 2023 and which is incorporated herein in its entirety by reference.

### FIELD

The description herein relates to the field of inspection and charged particle systems, and more particularly to methods for optimizing scanning of samples in inspection systems.

### BACKGROUND

In manufacturing processes of integrated circuits (ICs), unfinished or finished circuit components are inspected to ensure that they are manufactured according to design and are free of defects. An inspection system utilizing an optical microscope typically has resolution down to a few hundred nanometers; and the resolution is limited by the wavelength of light. As the physical sizes of IC components continue to reduce down to sub-100 or even sub-10 nanometers, inspection systems capable of higher resolution than those utilizing optical microscopes are needed.

A charged particle (e.g., electron) beam microscope, such as a scanning electron microscope (SEM) or a transmission electron microscope (TEM), capable of resolution down to less than a nanometer, serves as a practicable tool for inspecting IC components having a feature size that is sub-100 nanometers. With a SEM, electrons of a single primary electron beam, or electrons of a plurality of primary electron beams, can be focused on locations of interest of a wafer under inspection. The primary electrons interact with the wafer and may be backscattered or may cause the wafer to emit secondary electrons. The intensity of the electron beams comprising the backscattered electrons and the secondary electrons may vary based on the properties of the internal and external structures of the wafer, and thereby may indicate whether the wafer has defects.

### SUMMARY

Embodiments of the present disclosure provide systems and methods for optimizing scanning of a sample in inspection systems. In some embodiments, systems, methods, and non-transitory computer readable mediums may include providing a plurality of charged particle beams for scanning a first sample; identifying one or more failed charged particle beams of the plurality of charged particle beams; identifying one or more functional charged particle beams of the plurality of charged particle beams that scan the first sample; generating a beam map based on the identified one or more failed charged particle beams and the identified one or more functional charged particle beams, wherein the generated beam map excludes the identified one or more failed charged particle beams; and developing a scanning strategy based on the generated beam map for scanning the first sample or a second sample.

In some embodiments, systems, methods, and non-transitory computer readable mediums may include scanning a first sample; generating a beam map based on one or more failed charged particle beams of the scanning and one or functional charged particle beams of the scanning; developing a scanning strategy based on the generated beam map; and scanning the first sample or a second sample according to the scanning strategy.

In some embodiments, systems, methods, and non-transitory computer readable mediums may include determining one or more beams of a multi-beam system that are failing; determining one or more beams of the multi-beam system that are functioning; generating a beam map based on the determination of one or more beams that are failing and the determination of one or more beams that are functioning; and developing a scanning strategy of a sample based on the generated beam map.

### BRIEF DESCRIPTION OF THE DRAWINGS

FIG. 1 is a schematic diagram illustrating an exemplary electron beam inspection (EBI) system, consistent with embodiments of the present disclosure.

FIG. 2A is a schematic diagram illustrating an exemplary multi-beam system that is part of the exemplary charged particle beam inspection system of FIG. 1, consistent with embodiments of the present disclosure.

FIG. 2B is a schematic diagram illustrating an exemplary single-beam system that is part of the exemplary charged particle beam inspection system of FIG. 1, consistent with embodiments of the present disclosure.

FIG. 3 shows an exemplary beam map corresponding to a multi-beam system, consistent with embodiments of the present disclosure.

FIG. 4 shows an exemplary missing spot map corresponding to a multi-beam system, consistent with embodiments of the present disclosure.

FIG. 5 shows an exemplary construction of an optimized beam map corresponding to a multi-beam system, consistent with embodiments of the present disclosure.

FIG. 6A shows an exemplary array with position labels, consistent with embodiments of the present disclosure.

FIG. 6B shows an exemplary optimized beam map, consistent with embodiments of the present disclosure.

FIG. 6C shows an exemplary beam map.

FIG. 6D shows an exemplary graph, consistent with embodiments of the present disclosure.

FIG. 7 shows an exemplary process for optimizing scanning of a sample, consistent with embodiments of the present disclosure.

### DETAILED DESCRIPTION

Reference will now be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the disclosure. Instead, they are merely examples of apparatuses and methods consistent with aspects related to the subject matter recited in the appended claims. For example, although some embodiments are described in the context of utilizing electron beams, the disclosure is not so limited. Other types of charged particle beams may be similarly applied. Furthermore, other imaging systems may be used, such as optical imaging, photodetection, x-ray detection, extreme ultraviolet inspection, deep ultraviolet inspection, or the like, in which they generate corresponding types of images.

Electronic devices are constructed of circuits formed on a piece of silicon called a substrate. Many circuits may be formed together on the same piece of silicon and are called integrated circuits or ICs. The size of these circuits has decreased dramatically so that many more of them can fit on the substrate. For example, an IC chip in a smart phone can be as small as a thumbnail and yet may include over 2 billion transistors, the size of each transistor being less than 1/1000th the size of a human hair.

Making these extremely small ICs is a complex, time-consuming, and expensive process, often involving hundreds of individual steps. Errors in even one step have the potential to result in defects in the finished IC rendering it useless. Thus, one goal of the manufacturing process is to avoid such defects to maximize the number of functional ICs made in the process, that is, to improve the overall yield of the process.

One component of improving yield is monitoring the chip making process to ensure that it is producing a sufficient number of functional ICs. One way to monitor the process is to inspect the chip circuit structures at various stages of their formation. Inspection may be carried out using a scanning electron microscope (SEM). A SEM can be used to image these extremely small structures, in effect, taking a “picture” of the structures of the wafer. The image can be used to determine if the structure was formed properly, and also if it was formed at the proper location. If the structure is defective, then the process can be adjusted so the defect is less likely to recur. Defects may be generated during various stages of semiconductor processing. For the reason stated above, it is important to find defects accurately and efficiently as early as possible.

The working principle of a SEM is similar to a camera. A camera takes a picture by receiving and recording brightness and colors of light reflected or emitted from people or objects. A SEM takes a “picture” by receiving and recording energies or quantities of electrons reflected or emitted from the structures. Before taking such a “picture,” an electron beam may be projected onto the structures, and when the electrons are reflected or emitted (“exiting”) from the structures, a detector of the SEM may receive and record the energies or quantities of those electrons to generate an image. To take such a “picture,” some SEMs use a single electron beam (referred to as a “single-beam SEM”), while some SEMs use multiple electron beams (referred to as a “multi-beam SEM”) to take multiple “pictures” of the wafer. By using multiple electron beams, the SEM may project more electron beams onto the structures for obtaining these multiple “pictures,” resulting in more electrons exiting from the structures. Accordingly, the detector may receive more exiting electrons simultaneously, and generate images of the structures of the wafer with a higher efficiency and a faster speed.

In multi-beam inspection systems, a percentage of beams fail during inspection. These inspection systems generate poor or no images due to the failed beams, thereby resulting in image capture rate loss and in missing defects in samples. For example, beam failure may occur due to particles blocking one or more beams or due to discharge between the micro-electromechanical systems (MEMS) area with other ground surfaces in the inspection system, which may result in large spots on the generated images.

Typical inspection systems, however, suffer from constraints. Typical inspection systems are not able to re-acquire any images from the locations on the sample that were scanned with failing beams, which results in the generation of poor images and in defects remaining undetected by the inspection system, thereby decreasing throughput of the inspection system.

The disclosed embodiments provide systems and methods that address some or all of these disadvantages by optimizing the scanning of samples. The disclosed embodiments may include providing a plurality of charged particle beams to a first sample; identifying one or more failed charged particle beams of the plurality of charged particle beams; generating a beam map based on the identified one or more failed charged particle beams; developing a scanning strategy based on the beam map; and providing one or more charged particle beams of the plurality of charged particle beams to a second sample according to the scanning strategy. For example, by identifying one or more failed charged particle beams and generating a corresponding beam map, inspection systems may develop a scanning strategy such that areas of the sample corresponding to failed charged particle beams may be scanned by functional charged particle beams.

In some embodiments, the first sample may be a test sample with a predetermined pattern and the second sample may be the inspection sample. By scanning a test sample and identifying the failed charged particle beams first, a robust scanning strategy may be developed such that functional charged particle beams are provided to the inspection sample. Accordingly, the disclosed embodiments may reduce image capture rate loss and identify defects in samples during inspection. As a result, the disclosed embodiments may generate higher quality images, detect defects in samples, and increase throughput of the inspection system.

In some embodiments, the first sample may be the second sample. That is, the disclosed embodiments may only scan a sample during inspection. By scanning the sample during inspection and identifying the failed charged particle beams, a high throughput scanning strategy may be developed such that areas of the inspection sample that are scanned with failed charged particle beams may be re-scanned by functional charged particle beams. Accordingly, the disclosed embodiments may reduce image capture rate loss and identify defects in samples during inspection. As a result, the disclosed embodiments may generate higher quality images, detect defects in samples, and increase throughput of the inspection system.

Relative dimensions of components in drawings may be exaggerated for clarity. Within the following description of drawings, the same or like reference numbers refer to the same or like components or entities, and only the differences with respect to the individual embodiments are described.

As used herein, unless specifically stated otherwise, the term “or” encompasses all possible combinations, except where infeasible. For example, if it is stated that a component may include A or B, then, unless specifically stated otherwise or infeasible, the component may include A, or B, or A and B. As a second example, if it is stated that a component may include A, B, or C, then, unless specifically stated otherwise or infeasible, the component may include A, or B, or C, or A and B, or A and C, or B and C, or A and B and C.

Without limiting the scope of the present disclosure, some embodiments may be described in the context of providing detectors and detection methods in systems utilizing electron beams. However, the disclosure is not so limited. Other types of charged particle beams may be similarly applied. Furthermore, systems and methods for detection may be used in other imaging systems, such as optical imaging, photon detection, x-ray detection, ion detection, etc.

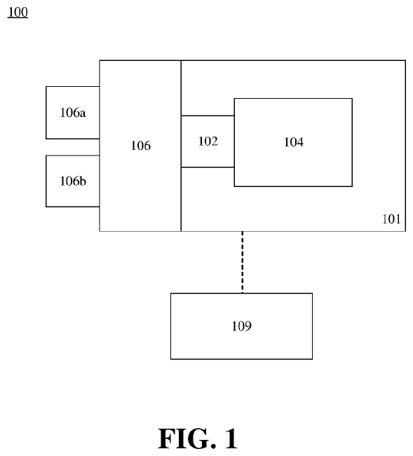

F g. 1 illustrates an exemplary electron beam inspection (EBI) system 100 consistent with embodiments of the present disclosure. EBI system 100 may be used for imaging. As shown in FIG. 1, EBI system 100 includes a main chamber 101, a load/lock chamber 102, an electron beam tool 104, and an equipment front end module (EFEM) 106. Electron beam tool 104 is located within main chamber 101. EFEM 106 includes a first loading port 106a and a second loading port 106b. EFEM 106 may include additional loading port(s). First loading port 106a and second loading port 106b receive wafer front opening unified pods (FOUPs) that contain wafers (e.g., semiconductor wafers or wafers made of other material(s)) or samples to be inspected (wafers and samples may be used interchangeably). A “lot” is a plurality of wafers that may be loaded for processing as a batch.

One or more robotic arms (not shown) in EFEM 106 may transport the wafers to load/lock chamber 102. Load/lock chamber 102 is connected to a load/lock vacuum pump system (not shown) which removes gas molecules in load/lock chamber 102 to reach a first pressure below the atmospheric pressure. After reaching the first pressure, one or more robotic arms (not shown) may transport the wafer from load/lock chamber 102 to main chamber 101. Main chamber 101 is connected to a main chamber vacuum pump system (not shown) which removes gas molecules in main chamber 101 to reach a second pressure below the first pressure. After reaching the second pressure, the wafer is subject to inspection by electron beam tool 104. Electron beam tool 104 may be a single-beam system or a multi-beam system.

A controller 109 is electronically connected to electron beam tool 104. Controller 109 may be a computer configured to execute various controls of EBI system 100. While controller 109 is shown in FIG. 1 as being outside of the structure that includes main chamber 101, load/lock chamber 102, and EFEM 106, it is appreciated that controller 109 may be a part of the structure.

In some embodiments, controller 109 may include one or more processors (not shown). A processor may be a generic or specific electronic device capable of manipulating or processing information. For example, the processor may include any combination of any number of a central processing unit (or “CPU”), a graphics processing unit (or “GPU”), an optical processor, a programmable logic controllers, a microcontroller, a microprocessor, a digital signal processor, an intellectual property (IP) core, a Programmable Logic Array (PLA), a Programmable Array Logic (PAL), a Generic Array Logic (GAL), a Complex Programmable Logic Device (CPLD), a Field-Programmable Gate Array (FPGA), a System On Chip (SoC), an Application-Specific Integrated Circuit (ASIC), and any type circuit capable of data processing. The processor may also be a virtual processor that includes one or more processors distributed across multiple machines or devices coupled via a network.

In some embodiments, controller 109 may further include one or more memories (not shown). A memory may be a generic or specific electronic device capable of storing codes and data accessible by the processor (e.g., via a bus). For example, the memory may include any combination of any number of a random-access memory (RAM), a read-only memory (ROM), an optical disc, a magnetic disk, a hard drive, a solid-state drive, a flash drive, a security digital (SD) card, a memory stick, a compact flash (CF) card, or any type of storage device. The codes may include an operating system (OS) and one or more application programs (or “apps”) for specific tasks. The memory may also be a virtual memory that includes one or more memories distributed across multiple machines or devices coupled via a network.

Embodiments of this disclosure may provide a single charged-particle beam imaging system (“single-beam system”). Compared with a single-beam system, a multiple charged-particle beam imaging system (“multi-beam system”) may be designed to optimize throughput for different scan modes. Embodiments of this disclosure provide a multi-beam system with the capability of optimizing throughput for different scan modes by using beam arrays with different geometries and adapting to different throughputs and resolution requirements.

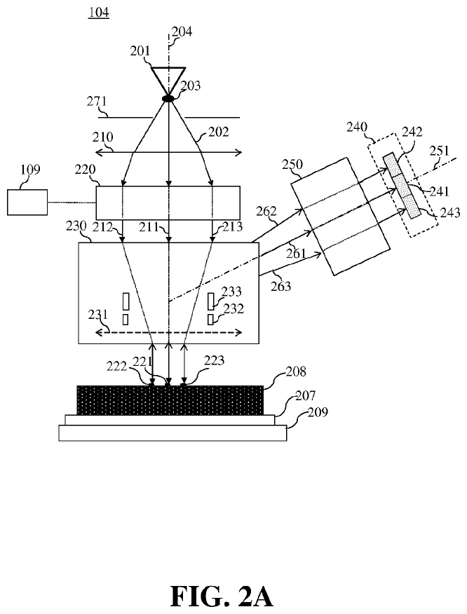

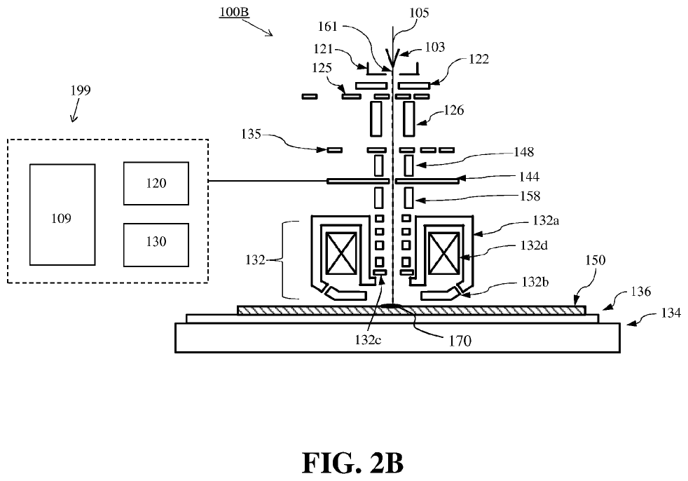

Reference is now made to FIG. 2A, which is a schematic diagram illustrating an exemplary electron beam tool 104 including a multi-beam inspection tool that is part of the EBI system 100 of FIG. 1, consistent with embodiments of the present disclosure. In some embodiments, electron beam tool 104 may be operated as a single-beam inspection tool that is part of EBI system 100 of FIG. 1. Multi-beam electron beam tool 104 (also referred to herein as apparatus 104) comprises an electron source 201, a Coulomb aperture plate (or “gun aperture plate”) 271, a condenser lens 210, a source conversion unit 220, a primary projection system 230, a motorized stage 209, and a sample holder 207 supported by motorized stage 209 to hold a sample 208 (e.g., a wafer or a photomask) to be inspected. Multi-beam electron beam tool 104 may further comprise a secondary projection system 250 and an electron detection device 240. Primary projection system 230 may comprise an objective lens 231. Electron detection device 240 may comprise a plurality of detection elements 241, 242, and 243. A beam separator 233 and a deflection scanning unit 232 may be positioned inside primary projection system 230.

Electron source 201, Coulomb aperture plate 271, condenser lens 210, source conversion unit 220, beam separator 233, deflection scanning unit 232, and primary projection system 230 may be aligned with a primary optical axis 204 of apparatus 104. Secondary projection system 250 and electron detection device 240 may be aligned with a secondary optical axis 251 of apparatus 104.

Electron source 201 may comprise a cathode (not shown) and an extractor or anode (not shown), in which, during operation, electron source 201 is configured to emit primary electrons from the cathode and the primary electrons are extracted or accelerated by the extractor and/or the anode to form a primary electron beam 202 that form a primary beam crossover (virtual or real) 203. Primary electron beam 202 may be visualized as being emitted from primary beam crossover 203.

Source conversion unit 220 may comprise an image-forming element array (not shown), an aberration compensator array (not shown), a beam-limit aperture array (not shown), and a pre-bending micro-deflector array (not shown). In some embodiments, the pre-bending micro-deflector array deflects a plurality of primary beamlets 211, 212, 213 of primary electron beam 202 to normally enter the beam-limit aperture array, the image-forming element array, and an aberration compensator array. In some embodiments, apparatus 104 may be operated as a single-beam system such that a single primary beamlet is generated. In some embodiments, condenser lens 210 is designed to focus primary electron beam 202 to become a parallel beam and be normally incident onto source conversion unit 220. The image-forming element array may comprise a plurality of micro-deflectors or micro-lenses to influence the plurality of primary beamlets 211, 212, 213 of primary electron beam 202 and to form a plurality of parallel images (virtual or real) of primary beam crossover 203, one for each of the primary beamlets 211, 212, and 213. In some embodiments, the aberration compensator array may comprise a field curvature compensator array (not shown) and an astigmatism compensator array (not shown). The field curvature compensator array may comprise a plurality of micro-lenses to compensate field curvature aberrations of the primary beamlets 211, 212, and 213. The astigmatism compensator array may comprise a plurality of micro-stigmators to compensate astigmatism aberrations of the primary beamlets 211, 212, and 213. The beam-limit aperture array may be configured to limit diameters of individual primary beamlets 211, 212, and 213. FIG. 2A shows three primary beamlets 211, 212, and 213 as an example, and it is appreciated that source conversion unit 220 may be configured to form any number of primary beamlets. Controller 109 may be connected to various parts of EBI system 100 of FIG. 1, such as source conversion unit 220, electron detection device 240, primary projection system 230, or motorized stage 209. In some embodiments, as explained in further details below, controller 109 may perform various image and signal processing functions. Controller 109 may also generate various control signals to govern operations of the charged particle beam inspection system.

Condenser lens 210 is configured to focus primary electron beam 202. Condenser lens 210 may further be configured to adjust electric currents of primary beamlets 211, 212, and 213 downstream of source conversion unit 220 by varying the focusing power of condenser lens 210. Alternatively, the electric currents may be changed by altering the radial sizes of beam-limit apertures within the beam-limit aperture array corresponding to the individual primary beamlets. The electric currents may be changed by both altering the radial sizes of beam-limit apertures and the focusing power of condenser lens 210. Condenser lens 210 may be an adjustable condenser lens that may be configured so that the position of its first principal plane is movable. The adjustable condenser lens may be configured to be magnetic, which may result in off-axis beamlets 212 and 213 illuminating source conversion unit 220 with rotation angles. The rotation angles change with the focusing power or the position of the first principal plane of the adjustable condenser lens. Condenser lens 210 may be an anti-rotation condenser lens that may be configured to keep the rotation angles unchanged while the focusing power of condenser lens 210 is changed. In some embodiments, condenser lens 210 may be an adjustable anti-rotation condenser lens, in which the rotation angles do not change when its focusing power and the position of its first principal plane are varied.

Objective lens 231 may be configured to focus beamlets 211, 212, and 213 onto a sample 208 for inspection and may form, in the current embodiments, three probe spots 221, 222, and 223 on the surface of sample 208. Coulomb aperture plate 271, in operation, is configured to block off peripheral electrons of primary electron beam 202 to reduce Coulomb effect. The Coulomb effect may enlarge the size of each of probe spots 221, 222, and 223 of primary beamlets 211, 212, 213, and therefore deteriorate inspection resolution.

Beam separator 233 may, for example, be a Wien filter comprising an electrostatic deflector generating an electrostatic dipole field and a magnetic dipole field (not shown in FIG. 2A). In operation, beam separator 233 may be configured to exert an electrostatic force by electrostatic dipole field on individual electrons of primary beamlets 211, 212, and 213. The electrostatic force is equal in magnitude but opposite in direction to the magnetic force exerted by magnetic dipole field of beam separator 233 on the individual electrons. Primary beamlets 211, 212, and 213 may therefore pass at least substantially straight through beam separator 233 with at least substantially zero deflection angles.

Deflection scanning unit 232, in operation, is configured to deflect primary beamlets 211, 212, and 213 to scan probe spots 221, 222, and 223 across individual scanning areas in a section of the surface of sample 208. In response to incidence of primary beamlets 211, 212, and 213 or probe spots 221, 222, and 223 on sample 208, electrons emerge from sample 208 and generate three secondary electron beams 261, 262, and 263. Each of secondary electron beams 261, 262, and 263 typically comprise secondary electrons (having electron energy≤50 eV) and backscattered electrons (having electron energy between 50 eV and the landing energy of primary beamlets 211, 212, and 213). Beam separator 233 is configured to deflect secondary electron beams 261, 262, and 263 towards secondary projection system 250. Secondary projection system 250 subsequently focuses secondary electron beams 261, 262, and 263 onto detection elements 241, 242, and 243 of electron detection device 240. Detection elements 241, 242, and 243 are arranged to detect corresponding secondary electron beams 261, 262, and 263 and generate corresponding signals which are sent to controller 109 or a signal processing system (not shown), e.g., to construct images of the corresponding scanned areas of sample 208.

In some embodiments, detection elements 241, 242, and 243 detect corresponding secondary electron beams 261, 262, and 263, respectively, and generate corresponding intensity signal outputs (not shown) to an image processing system (e.g., controller 109). In some embodiments, each detection element 241, 242, and 243 may comprise one or more pixels. The intensity signal output of a detection element may be a sum of signals generated by all the pixels within the detection element.

In some embodiments, controller 109 may comprise image processing system that includes an image acquirer (not shown), a storage (not shown). The image acquirer may comprise one or more processors. For example, the image acquirer may comprise a computer, server, mainframe host, terminals, personal computer, any kind of mobile computing devices, and the like, or a combination thereof. The image acquirer may be communicatively coupled to electron detection device 240 of apparatus 104 through a medium such as an electrical conductor, optical fiber cable, portable storage media, IR, Bluetooth, internet, wireless network, wireless radio, among others, or a combination thereof. In some embodiments, the image acquirer may receive a signal from electron detection device 240 and may construct an image. The image acquirer may thus acquire images of sample 208. The image acquirer may also perform various post-processing functions, such as generating contours, superimposing indicators on an acquired image, and the like. The image acquirer may be configured to perform adjustments of brightness and contrast, etc. of acquired images. In some embodiments, the storage may be a storage medium such as a hard disk, flash drive, cloud storage, random access memory (RAM), other types of computer readable memory, and the like. The storage may be coupled with the image acquirer and may be used for saving scanned raw image data as original images, and post-processed images.

In some embodiments, the image acquirer may acquire one or more images of a sample based on an imaging signal received from electron detection device 240. An imaging signal may correspond to a scanning operation for conducting charged particle imaging. An acquired image may be a single image comprising a plurality of imaging areas. The single image may be stored in the storage. The single image may be an original image that may be divided into a plurality of regions. Each of the regions may comprise one imaging area containing a feature of sample 208. The acquired images may comprise multiple images of a single imaging area of sample 208 sampled multiple times over a time sequence. The multiple images may be stored in the storage. In some embodiments, controller 109 may be configured to perform image processing steps with the multiple images of the same location of sample 208.

In some embodiments, controller 109 may include measurement circuitries (e.g., analog-to-digital converters) to obtain a distribution of the detected secondary electrons. The electron distribution data collected during a detection time window, in combination with corresponding scan path data of each of primary beamlets 211, 212, and 213 incident on the wafer surface, can be used to reconstruct images of the wafer structures under inspection. The reconstructed images can be used to reveal various features of the internal or external structures of sample 208, and thereby can be used to reveal any defects that may exist in the wafer.

In some embodiments, controller 109 may control motorized stage 209 to move sample 208 during inspection of sample 208. In some embodiments, controller 109 may enable motorized stage 209 to move sample 208 in a direction continuously at a constant speed. In other embodiments, controller 109 may enable motorized stage 209 to change the speed of the movement of sample 208 over time depending on the steps of scanning process.

Although FIG. 2A shows that apparatus 104 uses three primary electron beams, it is appreciated that apparatus 104 may use one, two, or more number of primary electron beams. The present disclosure does not limit the number of primary electron beams used in apparatus 104. In some embodiments, apparatus 104 may be a SEM used for lithography. In some embodiments, electron beam tool 104 may be a single-beam system or a multi-beam system.

For example, as shown in FIG. 2B, an electron beam tool 100B (also referred to herein as apparatus 100B) may be a single-beam inspection tool that is used in EBI system 10, consistent with embodiments of the present disclosure. Apparatus 100B includes a wafer holder 136 supported by motorized stage 134 to hold a wafer 150 to be inspected. Electron beam tool 100B includes an electron emitter, which may comprise a cathode 103, an anode 121, and a gun aperture 122. Electron beam tool 100B further includes a beam limit aperture 125, a condenser lens 126, a column aperture 135, an objective lens assembly 132, and a detector 144. Objective lens assembly 132, in some embodiments, may be a modified SORIL lens, which includes a pole piece 132a, a control electrode 132b, a deflector 132c, and an exciting coil 132d. In an imaging process, an electron beam 161 emanating from the tip of cathode 103 may be accelerated by anode 121 voltage, pass through gun aperture 122, beam limit aperture 125, condenser lens 126, and be focused into a probe spot 170 by the modified SORIL lens and impinge onto the surface of wafer 150. Probe spot 170 may be scanned across the surface of wafer 150 by a deflector, such as deflector 132c or other deflectors in the SORIL lens. Secondary or scattered primary particles, such as secondary electrons or scattered primary electrons emanated from the wafer surface may be collected by detector 144 to determine intensity of the beam and so that an image of an area of interest on wafer 150 may be reconstructed.

There may also be provided an image processing system 199 that includes an image acquirer 120, a storage 130, and controller 109. Image acquirer 120 may comprise one or more processors. For example, image acquirer 120 may comprise a computer, server, mainframe host, terminals, personal computer, any kind of mobile computing devices, and the like, or a combination thereof. Image acquirer 120 may connect with detector 144 of electron beam tool 100B through a medium such as an electrical conductor, optical fiber cable, portable storage media, IR, Bluetooth, internet, wireless network, wireless radio, or a combination thereof. Image acquirer 120 may receive a signal from detector 144 and may construct an image. Image acquirer 120 may thus acquire images of wafer 150. Image acquirer 120 may also perform various post-processing functions, such as generating contours, superimposing indicators on an acquired image, and the like. Image acquirer 120 may be configured to perform adjustments of brightness and contrast, etc. of acquired images. Storage 130 may be a storage medium such as a hard disk, random access memory (RAM), cloud storage, other types of computer readable memory, and the like. Storage 130 may be coupled with image acquirer 120 and may be used for saving scanned raw image data as original images, and post-processed images. Image acquirer 120 and storage 130 may be connected to controller 109. In some embodiments, image acquirer 120, storage 130, and controller 109 may be integrated together as one electronic control unit.

In some embodiments, image acquirer 120 may acquire one or more images of a sample based on an imaging signal received from detector 144. An imaging signal may correspond to a scanning operation for conducting charged particle imaging. An acquired image may be a single image comprising a plurality of imaging areas that may contain various features of wafer 150. The single image may be stored in storage 130. Imaging may be performed on the basis of imaging frames.

The condenser and illumination optics of the electron beam tool may comprise or be supplemented by electromagnetic quadrupole electron lenses. For example, as shown in FIG. 2B, electron beam tool 100B may comprise a first quadrupole lens 148 and a second quadrupole lens 158. In some embodiments, the quadrupole lenses are used for controlling the electron beam. For example, first quadrupole lens 148 can be controlled to adjust the beam current and second quadrupole lens 158 can be controlled to adjust the beam spot size and beam shape.

FIG. 2B illustrates a charged particle beam apparatus in which an inspection system may use a single primary beam that may be configured to generate secondary electrons by interacting with wafer 150. Detector 144 may be placed along optical axis 105, as in the embodiment shown in FIG. 2B. The primary electron beam may be configured to travel along optical axis 105. Accordingly, detector 144 may include a hole at its center so that the primary electron beam may pass through to reach wafer 150.

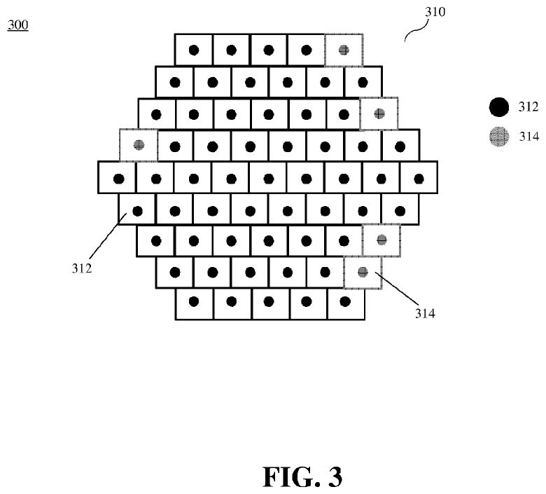

Reference is now made to FIG. 3, an exemplary beam map 300 corresponding to a multi-beam system (e.g., EBI system 100 of FIG. 1, multi-beam electron beam tool 104 of FIG. 2A), consistent with embodiments of the present disclosure. In some embodiments, a multi-beam system may generate beam map 300 upon a first scan of a sample, where the first scan may include providing a plurality of charged particle beams to the sample. Beam map 300 may show an array 310 corresponding to a plurality of charged particle beams (e.g., primary electron beam 202 of FIG. 2A) of a multi-beam system. For example, array 310 may show a layout of a plurality of charged particle beams that are provided to a sample (e.g., sample 208 of FIG. 2A) of the multi-beam system. In some embodiments, array 310 may include at least one functional charged particle beam 312 and at least one failed charged particle beam 314. In some embodiments, a system may not re-scan areas of a sample if beam map 300 shows that the percentage of failed charged particle beams of the array are below a certain threshold (e.g., if failed charged particle beams comprise 5% or less of the array).

For example, functional charged particle beam 312 may correspond to a working charged particle beam that properly scans an area of the sample and failed charged particle beam 314 may correspond to a failing charged particle beam that does not properly scan (e.g., does not scan) an area of the sample.

In some embodiments, a system may scan a first sample by providing a plurality of charged particle beams to the first sample. The first sample may be a test sample with a predetermined pattern and the second sample may be an inspection sample. For example, the test sample may have a predetermined pattern such that the system knows the pattern and each charged particle beam scans the same feature on the test sample. In some embodiments, the predetermined pattern may be a layout design, which may be stored in a layout file for a wafer design. The layout file can be in a Graphic Database System (GDS) format, Graphic Database System II (GDS II) format, an Open Artwork System Interchange Standard (OASIS) format, a Caltech Intermediate Format (CIF), etc. The wafer design may include patterns or structures for inclusion on the wafer. The patterns or structures can be mask patterns used to transfer features from the photolithography masks or reticles to a wafer. In some embodiments, a layout in GDS or OASIS format, among others, may comprise feature information stored in a binary file format representing planar geometric shapes, text, and other information related to the wafer design. In some embodiments, a layout design may correspond to a FOV of an inspection system (e.g., a FOV of an inspection system may include one or more layout structures of a layout design).

In some embodiments, a system may identify one or more failed charged particle beams of an array of charged particle beams and generate beam map 300 based on the one or more identified failed charged particle beams.

In some embodiments, a system may identify the one or more failed charged particle beams by generating a grey level histogram for each charged particle beam of an array of charged particle beams. For example, each pixel of an image of the test sample generated as a result of functional charged particle beams has a corresponding grey level. Since the pattern on the test sample is predetermined, based on the generated grey level histogram for each charged particle beam, the system can identify whether an image was generated as a result of functional charged particle beams and whether any of the charged particle beams failed.

For example, a charged particle beam may fail as a result of the beam being defocused or blocked. A beam may become defocused due to misalignment of a MEMS component or blocked due to one or more components blocking one or more beams. In some instances, a charged particle beam may fail due to discharge between a MEMS component area with other ground surfaces in the inspection system, which may result in large spots on the generated images.

In some embodiments, a grey level over an entire generated image being dull, monotone, or having a low (e.g., gradual) gradient may be indicative of one or more failed charged particle beams.

In some embodiments, a system may identify the one or more failed charged particle beams by determining a sharpness or a resolution of an image generated as a result of an array of charged particle beams. For example, an image of the test sample generated as a result of functional charged particle beams has a corresponding sharpness or resolution. Since the pattern on the test sample is predetermined, based on the on a sharpness or a resolution of a generated image, the system can identify whether an image was generated as a result of functional charged particle beams and whether any of the charged particle beams failed.

In some embodiments, a generated image of the test sample having a sharpness or resolution that differs from the expected (e.g., known) sharpness or resolution may be indicative of one or more failed charged particle beams.

In some embodiments, a system may develop a scanning strategy based on generated beam map 300, where generated beam map 300 corresponds to a beam map of a scanned test sample. In some embodiments, a system may scan an inspection sample (e.g., sample 208 of FIG. 2A, wafer 150 of FIG. 2B) by providing one or more charged particle beams (e.g., functional charged particle beam 312, primary electron beam 202 of FIG. 2A, electron beam 161 of FIG. 2B), excluding any failed charged particle beams 314, to the inspection sample according to the scanning strategy. In some embodiments, the scanning strategy may include providing one or more charged particle beams to one or more areas of the inspection sample corresponding to identified failed charged particle beams (e.g., failed charged particle beams 314). That is, the one or more charged particle beams used to scan the inspection sample may be a subset of the charged particle beams used to scan the test sample, where the subset excludes failed charged particle beams such that the inspection sample is scanned by only functional charged particle beams.

By scanning a test sample and identifying the failed charged particle beams before scanning an inspection sample, a robust scanning strategy may be developed such that functional charged particle beams are provided to the inspection sample. Accordingly, the disclosed embodiments may reduce image capture rate loss and identify defects in samples during inspection. As a result, the disclosed embodiments may generate higher quality images, detect defects in samples, and increase throughput of the inspection system.

In some embodiments, a system may develop a scanning strategy based on generated beam map 300 and the layout design corresponding to the predetermined pattern. For example, based on the layout design, the system may identify higher priority areas of a sample and lower priority areas of the sample. For example, higher priority areas of the sample may be areas of the sample that need to be scanned or inspected more than lower priority areas of the sample. In some embodiments, the system may develop a scanning strategy by arranging an array of charged particle beams (e.g., by positioning the array, by shifting the array, by rotating the array, by re-arranging the charged particle beams of the array, etc.) such that the identified one or more failed charged particle beams scan (e.g., are aligned with) lower priority areas of the sample during inspection and identified one or more functional charged particle beams can (e.g., are aligned with) higher priority areas of the sample during inspection.

In some embodiments, a system may scan an inspection sample, without scanning a test sample or generating a beam map beforehand, by providing a plurality of charged particle beams to the inspection sample. The pattern of the inspection sample may be unknown to the system. In some embodiments, during an inspection scan of the inspection sample, a system may identify one or more failed charged particle beams of an array of charged particle beams and generate beam map 300 based on the one or more identified failed charged particle beams.

In some embodiments, a system may identify the one or more failed charged particle beams by generating a grey level histogram for a plurality of generated images associated with one or more charged particle beams of the array of charged particle beams used during the inspection scan. For example, the system may analyze a one or more images from the same charged particle beam to determine whether the grey level histogram changes over different locations of the inspection sample. Based on the system's analysis of one or more images from one or more charged particle beams, the system can identify the functional charged particle beams and any failed charged particle beams.

In some embodiments, a grey level histogram with little to no change over different locations of the inspection sample for a charged particle beam may be indicative of one or more failed charged particle beams.

In some embodiments, a system may identify the one or more failed charged particle beams by determining a sharpness or a resolution of one or more generated images associated with one or more charged particle beams of the array of charged particle beams used during the inspection scan. For example, an image of the inspection sample generated as a result of functional charged particle beams may have sharp edges (e.g., corresponding to a pattern being scanned by a functional charged particle beam). Sharp edges may be absent from an image of the inspection sample generated as a result of failed charged particle beams.

In some embodiments, a system may develop a scanning strategy based on generated beam map 300, where generated beam map 300 corresponds to a beam map of a scanned inspection sample. In some embodiments, a system may scan an inspection sample (e.g., sample 208 of FIG. 2A, wafer 150 of FIG. 2B) by providing one or more charged particle beams (e.g., functional charged particle beam 312), excluding any failed charged particle beams 314, to the inspection sample according to the scanning strategy. In some embodiments, the scanning strategy may include re-scanning the inspection sample by providing one or more charged particle beams (e.g., primary electron beam 202 of multi-beam tool 104 of FIG. 2A, electron beam 161 of single beam tool 100B of FIG. 2B) to one or more areas of the inspection sample corresponding to identified failed charged particle beams (e.g., failed charged particle beams 314). That is, the one or more charged particle beams used to re-scan the inspection sample may be a subset of the charged particle beams used in the initial scan of the inspection sample, where the subset excludes failed charged particle beams such that the inspection sample is scanned by only functional charged particle beams.

By scanning the sample during inspection and identifying the failed charged particle beams during inspection, a high throughput scanning strategy may be developed such that areas of the inspection sample that are scanned with failed charged particle beams may be re-scanned by functional charged particle beams. Accordingly, the disclosed embodiments may reduce image capture rate loss and identify defects in samples during inspection. As a result, the disclosed embodiments may generate higher quality images, detect defects in samples, and increase throughput of the inspection system.

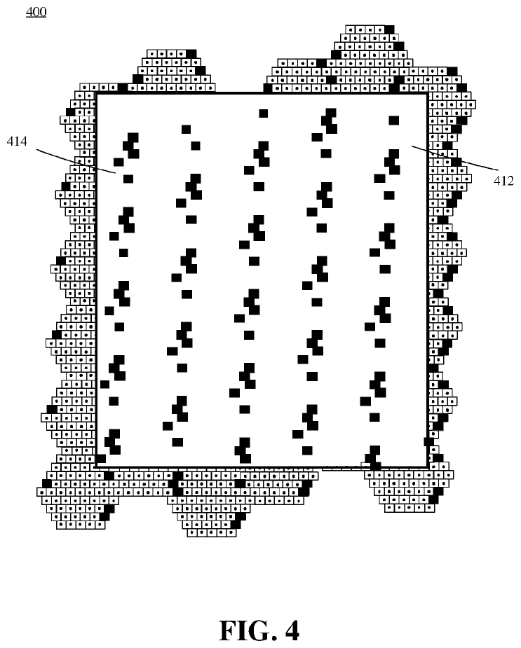

Reference is now made to FIG. 4, an exemplary missing spot map 400 corresponding to a multi-beam system (e.g., EBI system 100 of FIG. 1, multi-beam electron beam tool 104 of FIG. 2A), consistent with embodiments of the present disclosure. In some embodiments, a multi-beam system may generate missing spot map 400 based on a generated beam map (e.g., beam map 300 of FIG. 3). In some embodiments, a system may generate missing spot map 400 by arranging a plurality of generated beam maps within a field of view (FOV). In some embodiments, missing spot map 400 may include a care area 412 that includes areas of a sample (e.g., sample 208 of FIG. 2A, wafer 150 of FIG. 2B) that are scanned by functional charged particle beams (e.g., functional charged particle beams 312 of FIG. 3). In some embodiments, missing spot map 400 may include missing spots 414, which correspond to areas of a sample corresponding to failed charged particle beams (e.g., failed charged particle beams 314 of FIG. 3). That is, missing spots 414 may correspond to areas of a sample that are not scanned by a charged particle beam due to the failure of the charged particle beam.

In some embodiments, a system may scan a first sample by providing a plurality of charged particle beams to the first sample. The first sample may be a test sample with a predetermined pattern and the second sample may be an inspection sample. For example, the test sample may have a predetermined pattern such that the system knows the pattern and each charged particle beam scans the same feature on the test sample. In some embodiments, the predetermined pattern may be a layout design, which may be stored in a layout file for a wafer design. The layout file can be in a GDS format, GDS II format, an OASIS format, a CIF, etc. The wafer design may include patterns or structures for inclusion on the wafer. The patterns or structures can be mask patterns used to transfer features from the photolithography masks or reticles to a wafer. In some embodiments, a layout in GDS or OASIS format, among others, may comprise feature information stored in a binary file format representing planar geometric shapes, text, and other information related to the wafer design. In some embodiments, a layout design may correspond to a FOV of an inspection system (e.g., a FOV of an inspection system may include one or more layout structures of a layout design).

In some embodiments, a system may identify one or more failed charged particle beams of an array of charged particle beams, generate a beam map based on the one or more identified failed charged particle beams, and generate missing spot map 400 based on the generated beam map.

In some embodiments, a system may identify the one or more failed charged particle beams by generating a grey level histogram for each charged particle beam of an array of charged particle beams. For example, each pixel of an image of the test sample generated as a result of functional charged particle beams has a corresponding grey level. Since the pattern on the test sample is predetermined, based on the on a generated grey level histogram for each charged particle beam, the system can identify whether an image was generated as a result of functional charged particle beams and whether any of the charged particle beams failed.

For example, a charged particle beam may fail as a result of the beam being defocused or blocked. A beam may become defocused due to misalignment of a MEMS component or blocked due to misalignment or due to one or more particles blocking one or more beams. In some instances, a charged particle beam may fail due to discharge between a MEMS component area with other ground surfaces in the inspection system, which may result in large spots on the generated images.

In some embodiments, a grey level over an entire generated image being dull, monotone, or having a low (e.g., gradual) gradient may be indicative of one or more failed charged particle beams.

In some embodiments, a system may identify the one or more failed charged particle beams by determining a sharpness or a resolution of an image generated as a result of an array of charged particle beams. For example, an image of the test sample generated as a result of functional charged particle beams has a corresponding sharpness or resolution. Since the pattern on the test sample is predetermined, based on the on a sharpness or a resolution of a generated image, the system can identify whether an image was generated as a result of functional charged particle beams and whether any of the charged particle beams failed.

In some embodiments, a generated image of the test sample having a sharpness or resolution that differs from the expected (e.g., known) sharpness or resolution may be indicative of one or more failed charged particle beams.

In some embodiments, a system may develop a scanning strategy based on generated missing spot map 400, where generated missing spot map 400 corresponds to a missing spot map of a scanned test sample. In some embodiments, a system may scan an inspection sample (e.g., sample 208 of FIG. 2A, wafer 150 of FIG. 2B) by providing one or more charged particle beams (e.g., functional charged particle beam 312, primary electron beam 202 of FIG. 2A, electron beam 161 of FIG. 2B), excluding any failed charged particle beams (e.g., that correspond to missing spots 414), to the inspection sample according to the scanning strategy. In some embodiments, the scanning strategy may include providing one or more charged particle beams to missing spots 414, corresponding to one or more areas of the inspection sample corresponding to identified failed charged particle beams. That is, the one or more charged particle beams used to scan the inspection sample may be a subset of the charged particle beams used to scan the test sample, where the subset excludes failed charged particle beams such that the inspection sample is scanned by only functional charged particle beams.

By scanning a test sample and identifying the failed charged particle beams before scanning an inspection sample, a robust scanning strategy may be developed such that functional charged particle beams are provided to the inspection sample. Accordingly, the disclosed embodiments may reduce image capture rate loss and identify defects in samples during inspection. As a result, the disclosed embodiments may generate higher quality images, detect defects in samples, and increase throughput of the inspection system.

In some embodiments, a system may develop a scanning strategy based on generated missing spot map 400 and the layout design corresponding to the predetermined pattern. For example, based on the layout design, the system may identify higher priority areas of a sample and lower priority areas of the sample. For example, higher priority areas of the sample may be areas of the sample that need to be scanned or inspected more than lower priority areas of the sample. In some embodiments, the system may develop a scanning strategy by arranging an array of charged particle beams (e.g., by positioning the array, by shifting the array, by rotating the array, by re-arranging the charged particle beams of the array, etc.) such that the identified one or more failed charged particle beams scan (e.g., are aligned with) lower priority areas of the sample during inspection and identified one or more functional charged particle beams can (e.g., are aligned with) higher priority areas of the sample during inspection.

In some embodiments, a system may scan an inspection sample, without scanning a test sample or generating a beam map beforehand, by providing a plurality of charged particle beams to the inspection sample. The pattern of the inspection sample may be unknown to the system. In some embodiments, during an inspection scan of the inspection sample, a system may identify one or more failed charged particle beams of an array of charged particle beams, generate a beam map based on the one or more identified failed charged particle beams, and generate missing spot map 400 based on the generated beam map.

In some embodiments, a system may identify the one or more failed charged particle beams by generating a grey level histogram for a plurality of generated images associated with one or more charged particle beams of the array of charged particle beams used during the inspection scan. For example, the system may analyze a one or more images from the same charged particle beam to determine whether the grey level histogram changes over different locations of the inspection sample. Based on the system's analysis of one or more images from one or more charged particle beams, the system can identify the functional charged particle beams and any failed charged particle beams.

In some embodiments, a grey level histogram with little to no change over different locations of the inspection sample for a charged particle beam may be indicative of one or more failed charged particle beams.

In some embodiments, a system may identify the one or more failed charged particle beams by determining a sharpness or a resolution of one or more generated images associated with one or more charged particle beams of the array of charged particle beams used during the inspection scan. For example, an image of the inspection sample generated as a result of functional charged particle beams may have sharp edges (e.g., corresponding to a pattern being scanned by a functional charged particle beam). Sharp edges may be absent from an image of the inspection sample generated as a result of failed charged particle beams.

In some embodiments, a system may develop a scanning strategy based on generated missing spot map 400, where generated missing spot map 400 corresponds to a missing spot map of a scanned inspection sample. In some embodiments, a system may scan an inspection sample (e.g., sample 208 of FIG. 2A, wafer 150 of FIG. 2B) by providing one or more charged particle beams (e.g., functional charged particle beam 312), excluding any failed charged particle beams (e.g., that correspond to missing spots 414), to the inspection sample according to the scanning strategy. In some embodiments, the scanning strategy may include re-scanning the inspection sample by providing one or more charged particle beams (e.g., primary electron beam 202 of FIG. 2A, electron beam 161 of FIG. 2B) to missing spots 414, corresponding to one or more areas of the inspection sample corresponding to identified failed charged particle beams. That is, the one or more charged particle beams used to re-scan the inspection sample may be a subset of the charged particle beams used in the initial scan of the inspection sample, where the subset excludes failed charged particle beams such that the inspection sample is scanned by only functional charged particle beams.

By scanning the sample during inspection and identifying the failed charged particle beams during inspection, a high throughput scanning strategy may be developed such that areas of the inspection sample that are scanned with failed charged particle beams may be re-scanned by functional charged particle beams. Accordingly, the disclosed embodiments may reduce image capture rate loss and identify defects in samples during inspection. As a result, the disclosed embodiments may generate higher quality images, detect defects in samples, and increase throughput of the inspection system.

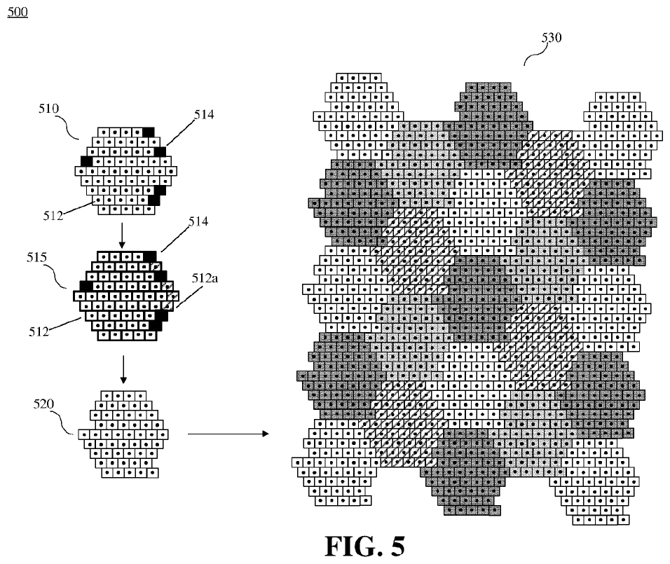

Reference is now made to FIG. 5, an exemplary construction 500 of an optimized beam map 530 corresponding to a multi-beam system (e.g., EBI system 100 of FIG. 1, multi-beam electron beam tool 104 of FIG. 2A), consistent with embodiments of the present disclosure. In some embodiments, a multi-beam system may generate a beam map 510 upon a first scan of a sample, where the first scan may include providing a plurality of charged particle beams to the sample. Beam map 510 may show an array corresponding to a plurality of charged particle beams (e.g., primary electron beam 202 of FIG. 2A, array 310 of FIG. 3) of a multi-beam system. For example, beam map 510 may show a layout of a plurality of charged particle beams that are provided to a sample (e.g., sample 208 of FIG. 2A) of the multi-beam system. In some embodiments, beam map 510 may include at least one functional charged particle beam 512 (e.g., functional charged particle beam 312 of FIG. 3) and at least one failed charged particle beam 514 (e.g., failed charged particle beam 314 of FIG. 3).

For example, functional charged particle beam 512 may correspond to a working charged particle beam that properly scans an area of the sample and failed charged particle beam 514 may correspond to a failing charged particle beam that does not properly scan (e.g., does not scan) an area of the sample.

In some embodiments, a system may scan a first sample by providing a plurality of charged particle beams to the first sample. The first sample may be a test sample with a predetermined pattern and the second sample may be an inspection sample. For example, the test sample may have a predetermined pattern such that the system knows the pattern, and each charged particle beam scans the same feature on the test sample. In some embodiments, a system may identify one or more failed charged particle beams of an array of charged particle beams and identify one or more functional charged particle beams of the array of charged particle beams that scan the test sample. In some embodiments, a system may generate beam map 510 based on the one or more identified failed charged particle beams and based on the one or more identified functional charged particle beams that scan the test sample.

In some embodiments, a system may identify the one or more failed charged particle beams by generating a grey level histogram for each charged particle beam of an array of charged particle beams. For example, each pixel of an image of the test sample generated as a result of functional charged particle beams has a corresponding grey level. Since the pattern on the test sample is predetermined, based on a generated grey level histogram for each charged particle beam, the system can identify whether an image was generated as a result of functional charged particle beams and whether any of the charged particle beams failed.

For example, a charged particle beam may fail as a result of the beam being defocused or blocked. A beam may become defocused due to misalignment of a MEMS component or blocked due to misalignment or due to one or more particles blocking one or more beams. In some instances, a charged particle beam may fail due to discharge between a MEMS component area with other ground surfaces in the inspection system, which may result in large spots on the generated images.

In some embodiments, a grey level over an entire generated image being dull, monotone, or having a low (e.g., gradual) gradient may be indicative of one or more failed charged particle beams.

In some embodiments, a system may identify the one or more failed charged particle beams by determining a sharpness or a resolution of an image generated as a result of an array of charged particle beams. For example, an image of the test sample generated as a result of functional charged particle beams has a corresponding sharpness or resolution. Since the pattern on the test sample is predetermined, based on the on a sharpness or a resolution of a generated image, the system can identify whether an image was generated as a result of functional charged particle beams and whether any of the charged particle beams failed.

In some embodiments, a generated image of the test sample having a sharpness or resolution that differs from the expected (e.g., known) sharpness or resolution may be indicative of one or more failed charged particle beams.

In some embodiments, a system may develop a scanning strategy based on generated beam map 510, where generated beam map 510 corresponds to a beam map of a scanned test sample. In some embodiments, a system may scan an inspection sample (e.g., sample 208 of FIG. 2A, wafer 150 of FIG. 2B) by providing one or more charged particle beams (e.g., functional charged particle beam 312, primary electron beam 202 of multi-beam tool 104 of FIG. 2A, electron beam 161 of single beam tool 100B of FIG. 2B), excluding any failed charged particle beams 514, to the inspection sample according to the scanning strategy. In some embodiments, the scanning strategy may include providing one or more charged particle beams to one or more areas of the inspection sample corresponding to identified failed charged particle beams (e.g., failed charged particle beams 514). That is, the one or more charged particle beams used to scan the inspection sample may be a subset of the charged particle beams used to scan the test sample, where the subset excludes failed charged particle beams such that the inspection sample is scanned by only functional charged particle beams. In some embodiments, the subset of the charged particle beams may exclude failed charged particle beams and exclude some functional charged particle beams.

For example, a system may generate a beam map 515 based on generated beam map 510. In some embodiments, beam map 515 may include functional charged particle beams 512 and identified failed charged particle beams 514. In some embodiments, beam map 515 may include identified functional charged particle beams 512a, which may correspond to functional charged particle beams that are excluded from optimized beam map 530. For example, identified functional charged particle beams 512a may be excluded from a beam map 520, and consequently from optimized beam map 530, to minimize overlapping of functional charged particle beams during scanning of an inspection sample.

In some embodiments, a system may generate beam map 520 that only includes function charged particle beams 512. A system may generate optimized beam map 530 by arranging a plurality of beam maps 520 in a FOV to optimize the FOV arrangement of functional charged particle beams. For example, by excluding identified failed charged particle beams 514 and by excluding identified functional charged particle beams from beam map 520, a system may arrange beam map 520 in a FOV to generate optimized beam map 530. In some embodiments, optimized beam map 530 may be used to minimize overlapping of functional charged particle beams (e.g., where different functional charged particle beams scan the same area of the inspection sample) during scanning of an inspection sample.

By scanning a test sample and identifying the failed charged particle beams before scanning an inspection sample, a robust scanning strategy may be developed such that functional charged particle beams are provided to the inspection sample with minimized overlapping. Accordingly, the disclosed embodiments may reduce image capture rate loss and identify defects in samples during inspection. As a result, the disclosed embodiments may generate higher quality images, detect defects in samples, and increase throughput of the inspection system.

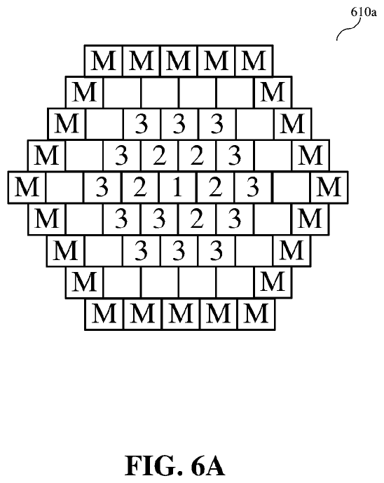

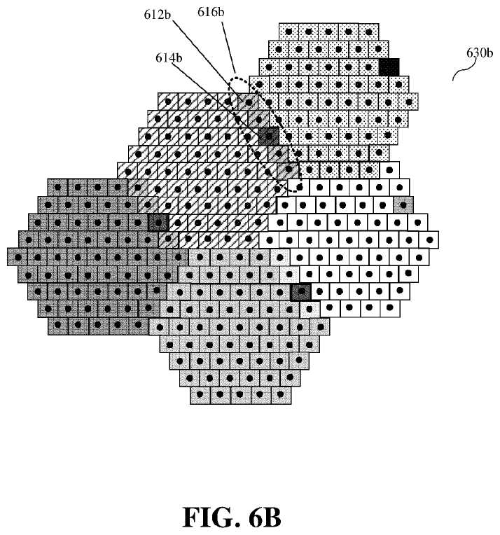

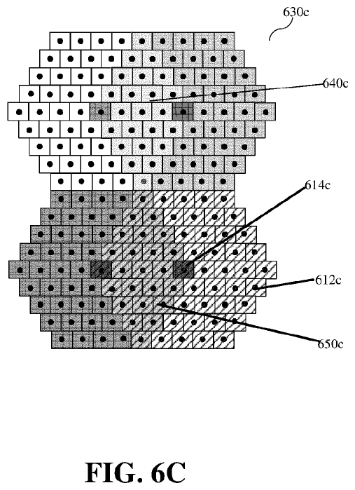

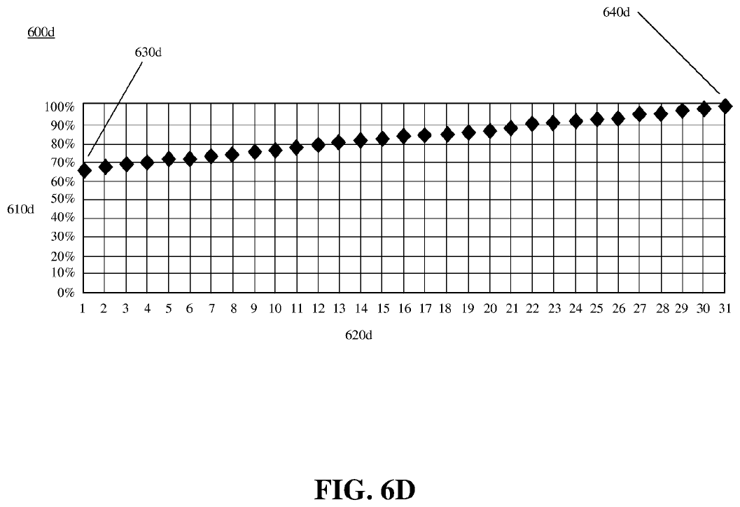

Reference is now made to FIG. 6A, an exemplary beam array 610a with position labels, consistent with embodiments of the present disclosure. Beam array 610a includes position labels 1 through M, where 1 corresponds to a charged particle beam in a 1^{st} ring in the center of beam array 610a and M corresponds to a charged particle beam in a Mth ring in the perimeter of beam array 610a. The lower position labels correspond to rings of charged particle beams that are closer to the center of beam array 610a. For example, position label 2 corresponds to a charged particle beam in a 2^{nd} ring from the center of beam array 610a and position label 3 corresponds to a charged particle beam in a 3^{rd} ring from the center of beam array 610a.

It should be understood that beam array 610a may include any number of rings of charged particle beams (e.g., M number of rings), and that the number of rings in a beam array are not limited to the number shown in FIG. 6A.

Reference is now made to FIG. 6B, an exemplary optimized beam map 630b, consistent with embodiments of the present disclosure.

In some embodiments, a system may generate an optimized beam map (e.g., optimized beam map 530 of FIG. 5, optimized beam map 630b of FIG. 6B) according to the location of a failed charged particle beam (e.g., failed charged particle beam 314 of FIG. 3, failed charged particle beam 514 of FIG. 5) in a multi-beam array (e.g., array 310 of FIG. 3). When failed charged particle beams are located in the perimeter of a multi-beam array (e.g., at position label M of beam array 610a), a system may optimize scanning during inspection by using a generated optimized beam map. A generated optimized beam map may optimize scanning in this case since multi-beam arrays may be arranged adjacent to each other in a FOV, thereby minimizing the number of areas on a sample that are scanned more than once by a functional charged particle beam.

For example, as shown in FIG. 6B, optimized beam map 630b may be generated to compensate for failed charged particle beam 614b by overlapping a set of functional beams 616b of a charged particle beam array including failed charged particle beam 614b (e.g., if the failed charged particle beam is on position label M, then M−1 beams overlap in the generated optimized beam map) and identified functional charged particle beams 612b (e.g., identified functional charged particle beams 512a of FIG. 5).

In some embodiments, an optimized beam map may be generated according to the following equations.

$$Total number of rings = M \qquad ( 1 )$$

$$Total beam number = \frac{{M}^{2} + M}{2} + 5 \cdot ( \frac{{M}^{2} + M}{2} - M ) - M + 1 \qquad ( 2 )$$

If a failed charged particle beam is on ring N of abeam array, and 1<N≤M, then the number of overlapping functional charged particle beams in the generated optimized beam map may be calculated by Equation (3) below.

$$( M - 1 ) \cdot ( M - N + 1 ) \qquad ( 3 )$$

Reference is now made to FIG. 6C, an exemplary beam map 630c. When failed charged particle beams are located closer to, or within the center of, a multi-beam array, then generating a rearranged beam map may not optimize scanning. For example, if a failed charged particle beam 614c is located at a center of a beam array (e.g., position label 1 of FIG. 6A), then beam map 630c will have M² overlapping functional charged particle beams. As shown in FIG. 6C, if a new beam map 630c is generated based on rearranged multi-beam arrays with failed charged particle beams 614c in the center of the multi-beam array, then more areas of a sample will be scanned more than once by functional charged particle beams 612c during inspection, thereby reducing inspection throughput. Overlapping areas 640c and 650c correspond to overlapping functional charged particle beams of a multi-beam array that scan areas of the sample more than once.

In embodiments where a failed charged particle beam is in the center of the multi-beam array, scanning may be optimized by first scanning an inspection sample with the multi-beam array, then in a second scan, scanning areas of the sample corresponding to failed charged particle beams with a single functional charged particle beam (as opposed to using a multi-beam tool on the second scan).

For example, turning back to FIG. 6A, if a failed charged particle beam is located at position label 1, then a multi-beam array may be used to scan areas of the sample corresponding to functional charged particle beams in rings 2−M and a single beam tool may be used to scan areas of the sample corresponding to position label 1. This method may minimize the number of areas on a sample that are scanned more than once by functional charged particle beams, thereby increasing inspection throughput.

Reference is now made to FIG. 6D, an exemplary graph 600d, consistent with embodiments of the present disclosure.

Graph 600d includes an axis 610d corresponding to the ring position (e.g., label positions 1-M of FIG. 6A) of a beam array on which a failed charged particle beam exists (e.g., failed charged particle beam 314 of FIG. 3, failed charged particle beam 414 of FIG. 4, failed charged particle beam 514 of FIG. 5, failed charged particle beam 614b of FIG. 6B, failed charged particle beam 614c of FIG. 6C). Graph 600d includes an axis 620d corresponding to an effective scanning area of a sample (e.g., an area of a sample that is scanned by functional charged particle beams) when a beam map is generated by arranging beam arrays in a FOV.

As shown by graph 600d, and consistent with FIG. 6A, FIG. 6B, and FIG. 6C described above, when a beam array includes a failed charged particle beam at or near the center of the beam array (e.g., at position label 1 of axis 620d), the effective scanning area of a sample is lower than when a beam array has a failed charged particle beam at or near the perimeter of the beam array (e.g., at position label 31 of axis 620d).

For example, data point 630d may correspond to an effective scanning area of a sample when beam map 630c of FIG. 6C is used to scan a sample while data point 640d may correspond to an effective scanning area of a sample when beam map 630b of FIG. 6B is used to scan a sample.

In some embodiments, a system may generate a beam map by arranging beam arrays in a FOV as described above for FIG. 5 and FIG. 6B by calculating a predicted effective scanning area based on the identified failed charged particle beams and the identified functional charged particle beams (e.g., identified functional charged particle beams 512a of FIG. 5).

For example, if the predicted effective scanning area is below a certain threshold (e.g., below a certain percentage effective scanning area), then a system may not generate a beam map by arranging beam arrays in a FOV. For example, a system may conduct a first scan of an inspection sample with a multi-beam array, then in a second scan, scan areas of the sample corresponding to failed charged particle beams with a single functional charged particle beam (e.g., using a multi-beam tool, using a single beam tool, etc.). For example, FIG. 6C may correspond to an example where the predicted effective scanning area is below a certain threshold.

If the predicted effective scanning area is above a certain threshold (e.g., above a certain percentage effective scanning area), then a system may generate an optimized beam map by arranging beam arrays in a FOV. For example, FIG. 5 and FIG. 6B may correspond to examples where the predicted effective scanning area is above a certain threshold.

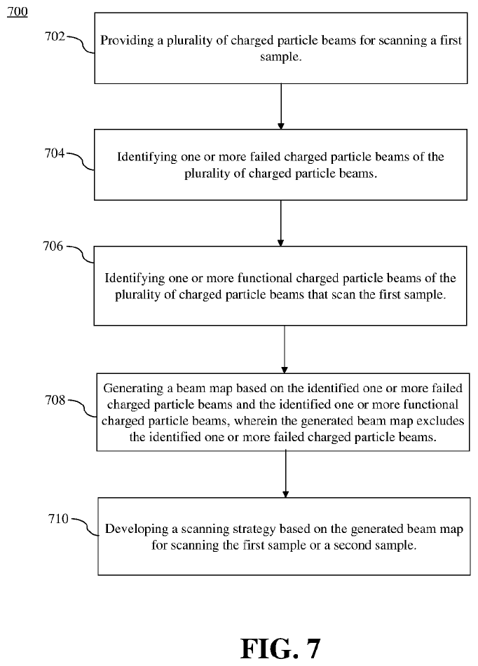

Reference is now made to FIG. 7, an exemplary process 700 for optimizing scanning of a sample, consistent with embodiments of the present disclosure.

In a first variation of process 700, at step 702, a system (e.g., controller 109 of FIG. 1) may scan a first sample (e.g., sample 208 of FIG. 2A) by providing a plurality of charged particle beams (e.g., primary electron beam 202 of FIG. 2A) for scanning the first sample. The first sample may be a test sample with a predetermined pattern and the second sample may be an inspection sample. For example, the test sample may have a predetermined pattern such that the system knows the pattern and each charged particle beam scans the same feature on the test sample.

At step 704, a system may identify one or more failed charged particle beams (e.g., failed charged particle beam 314 of FIG. 3, failed charged particle beam 514 of FIG. 5, failed charged particle beams 614b of FIG. 6B) of an array (e.g., array 310 of FIG. 3) of charged particle beams.

At step 706, a system may identify one or more functional charged particle beams (e.g., identified functional charged particle beams 512a of FIG. 5, identified functional charged particle beams 612b of FIG. 6B) of the array of charged particle beams that scan the test sample. In some embodiments, identified functional charged particle beams may correspond to functional charged particle beams that are excluded from an optimized beam map. For example, some identified functional charged particle beams may be excluded from an optimized beam map to minimize overlapping (e.g., set of functional beams 616b of FIG. 6B) of functional charged particle beams during scanning of an inspection sample.

At step 708, a system may generate a beam map (e.g., beam map 300 of FIG. 3, beam map 510 of FIG. 5) based on the one or more identified failed charged particle beams and the one or more identified functional charged particle beams, where the generated beam map excludes the identified one or more failed charged particle beams.

In some embodiments, a system may identify the one or more failed charged particle beams by generating a grey level histogram for each charged particle beam of an array of charged particle beams. For example, each pixel of an image of the test sample generated as a result of functional charged particle beams has a corresponding grey level. Since the pattern on the test sample is predetermined, based on the on a generated grey level histogram for each charged particle beam, the system can identify whether an image was generated as a result of functional charged particle beams and whether any of the charged particle beams failed.

For example, a charged particle beam may fail as a result of the beam being defocused or blocked. A beam may become defocused due to misalignment of a MEMS component or blocked due to one or more particles blocking one or more beams. In some instances, a charged particle beam may fail due to discharge between a MEMS component area with other ground surfaces in the inspection system, which may result in large spots on the generated images.

In some embodiments, a grey level over an entire generated image being dull, monotone, or having a low (e.g., gradual) gradient may be indicative of one or more failed charged particle beams.

In some embodiments, a system may identify the one or more failed charged particle beams by determining a sharpness or a resolution of an image generated as a result of an array of charged particle beams. For example, an image of the test sample generated as a result of functional charged particle beams has a corresponding sharpness or resolution. Since the pattern on the test sample is predetermined, based on the on a sharpness or a resolution of a generated image, the system can identify whether an image was generated as a result of functional charged particle beams and whether any of the charged particle beams failed.

In some embodiments, a generated image of the test sample having a sharpness or resolution that differs from the expected (e.g., known) sharpness or resolution may be indicative of one or more failed charged particle beams.

In some embodiments, as described above at step 706, functional charged particle beams may be excluded from an optimized beam map to minimize overlapping of functional charged particle beams during scanning of an inspection sample. By excluding identified failed charged particle beams and by excluding identified functional charged particle beams from a beam map, an optimized beam map may be used to minimize overlapping of functional charged particle beams during scanning of an inspection sample.

At step 710, a system may develop a scanning strategy based on the generated beam map for scanning the inspection sample (e.g., sample 208 of multi-beam tool 104 of FIG. 2A, wafer 150 of single beam tool 100B of FIG. 2B) by providing one or more charged particle beams (e.g., functional charged particle beam 312 of FIG. 3, functional charged particle beam 512 of FIG. 5, functional charged particle beam 612b of FIG. 6B, primary electron beam 202 of FIG. 2A, electron beam 161 of FIG. 2B), excluding any failed charged particle beams and any identified functional charged particle beams, to the inspection sample according to the scanning strategy. In some embodiments, the scanning strategy may include providing one or more charged particle beams to one or more areas of the inspection sample corresponding to identified failed charged particle beams. That is, the one or more charged particle beams used to scan the inspection sample may be a subset of the charged particle beams used to scan the test sample, where the subset excludes failed charged particle beams such that the inspection sample is scanned by only functional charged particle beams.

By scanning a test sample and identifying the failed charged particle beams before scanning an inspection sample, a robust scanning strategy may be developed such that functional charged particle beams are provided to the inspection sample with minimized overlapping. Accordingly, the disclosed embodiments may reduce image capture rate loss and identify defects in samples during inspection. As a result, the disclosed embodiments may generate higher quality images, detect defects in samples, and increase throughput of the inspection system.

In a second variation of process 700, at step 702, a system may scan an inspection sample, without scanning a test sample or generating a beam map beforehand, by providing a plurality of charged particle beams for scanning the inspection sample (e.g., sample 208 of FIG. 2A). The pattern of the inspection sample may be unknown to the system.

At step 704, during an inspection scan of the inspection sample, a system may identify one or more failed charged particle beams (e.g., failed charged particle beams 314 of FIG. 3) of an array (e.g., array 310 of FIG. 3) of charged particle beams.

At step 706, a system may identify one or more functional charged particle beams of the array of charged particle beams that scan the test sample.

At step 708, a system may generate a beam map (e.g., beam map 300 of FIG. 3) based on the one or more identified failed charged particle beams and the one or more identified functional charged particle beams, where the generated beam map excludes the identified one or more failed charged particle beams.

In some embodiments, a system may identify the one or more failed charged particle beams by generating a grey level histogram for a plurality of generated images associated with one or more charged particle beams of the array of charged particle beams used during the inspection scan. For example, the system may analyze a one or more images from the same charged particle beam to determine whether the grey level histogram changes over different locations of the inspection sample. Based on the system's analysis of one or more images from one or more charged particle beams, the system can identify the functional charged particle beams and any failed charged particle beams.

In some embodiments, a grey level histogram with little to no change over different locations of the inspection sample for a charged particle beam may be indicative of one or more failed charged particle beams.

In some embodiments, a system may identify the one or more failed charged particle beams by determining a sharpness or a resolution of one or more generated images associated with one or more charged particle beams of the array of charged particle beams used during the inspection scan. For example, an image of the inspection sample generated as a result of functional charged particle beams may have sharp edges (e.g., corresponding to a pattern being scanned by a functional charged particle beam). Sharp edges may be absent from an image of the inspection sample generated as a result of failed charged particle beams.

At step 710, a system may develop a scanning strategy based on the generated beam map for scanning the inspection sample (e.g., sample 208 of FIG. 2A, wafer 150 of FIG. 2B) by providing one or more charged particle beams (e.g., functional charged particle beam 312 of FIG. 3), excluding any failed charged particle beams, to the inspection sample according to the scanning strategy. In some embodiments, the scanning strategy may include re-scanning the inspection sample by providing one or more charged particle beams (e.g., primary electron beam 202 of multi-beam tool 104 of FIG. 2A, electron beam 161 of single beam tool 100B of FIG. 2B) to one or more areas of the inspection sample corresponding to identified failed charged particle beams. That is, the one or more charged particle beams used to re-scan the inspection sample may be a subset of the charged particle beams used in the initial scan of the inspection sample, where the subset excludes failed charged particle beams such that the inspection sample is scanned by only functional charged particle beams. In this variation of process 700, the second sample is the first sample.

By scanning the sample during inspection and identifying the failed charged particle beams during inspection, a high throughput scanning strategy may be developed such that areas of the inspection sample that are scanned with failed charged particle beams may be re-scanned by functional charged particle beams. Accordingly, the disclosed embodiments may reduce image capture rate loss and identify defects in samples during inspection. As a result, the disclosed embodiments may generate higher quality images, detect defects in samples, and increase throughput of the inspection system.

A non-transitory computer readable medium may be provided that stores instructions for a processor of a controller (e.g., controller 109 of FIG. 1) for controlling the electron beam tool or other systems of other systems and servers, or components thereof, consistent with embodiments in the present disclosure. These instructions may allow the one or more processors to carry out image processing, data processing, beamlet scanning, graphical display, operations of a charged particle beam apparatus, or another imaging device, or the like for providing operations consistent with those described above for FIGS. 3-5 and 7. In some embodiments, the non-transitory computer readable medium may be provided that stores instructions for a processor to perform the steps of process 700. Common forms of non-transitory media include, for example, a floppy disk, a flexible disk, hard disk, solid state drive, magnetic tape, or any other magnetic data storage medium, a Compact Disc Read Only Memory (CD-ROM), any other optical data storage medium, any physical medium with patterns of holes, a Random Access Memory (RAM), a Programmable Read Only Memory (PROM), and Erasable Programmable Read Only Memory (EPROM), a FLASH-EPROM or any other flash memory, Non-Volatile Random Access Memory (NVRAM), a cache, a register, any other memory chip or cartridge, and networked versions of the same.

The embodiments may further be described using the following clauses:
1. A method for optimizing scanning of a sample, comprising:
providing a plurality of charged particle beams for scanning a first sample;
identifying one or more failed charged particle beams of the plurality of charged particle beams;
identifying one or more functional charged particle beams of the plurality of charged particle beams that scan the first sample;
generating a beam map based on the identified one or more failed charged particle beams and the identified one or more functional charged particle beams, wherein the generated beam map excludes the identified one or more failed charged particle beams; and
developing a scanning strategy based on the generated beam map for scanning the first sample or a second sample.
2. The method of clause 1, wherein identifying the one or more failed charged particle beams comprises generating a grey level histogram for each charged particle beam of the plurality of charged particle beams.
3. The method of any one of clauses 1-2, wherein identifying the one or more failed charged particle beams comprises determining any one of a sharpness or a resolution of an image generated as a result of the plurality of charged particle beams.
4. The method of clause 1, wherein identifying the one or more failed charged particle beams comprises generating a grey level histogram for a plurality of images associated with a first charged particle beam to determine whether the first charge particle beam is failing.
5. The method of any one of clauses 1 or 4, wherein identifying the one or more failed charged particle beams comprises determining any one of a sharpness or a resolution of a plurality of images associated with a first charged particle beam to determine whether the first charge particle beam is failing.
6. The method of any one of clauses 1-3, wherein the first sample has a predetermined pattern.
7. The method of any one of clauses 1-3 or 6, wherein generating the beam map excludes some of the identified one or more functional charged particle beams.
8. The method of any one of clauses 1-3 or 6-7, wherein the generated beam map is used to minimize overlapping of functional charged particle beams during scanning of the second sample.
9. The method of any one of clauses 1-3 or 6-8, wherein the scanning strategy comprises using the generated beam map to scan the second sample.
10. The method of any one of clauses 1-3 or 6-9, wherein the generated beam map is used to maximize scanning of the second sample.
11. The method of any one of clauses 1-3 or 6-10, wherein the scanning strategy comprises providing a charged particle beam to an area of the second sample corresponding to the identified one or more failed charged particle beams.
12. The method of any one of clauses 1, 4, or 5, wherein the scanning strategy comprises providing a charged particle beam to an area of the first sample corresponding to the identified one or more failed charged particle beams.
13. A method for optimizing scanning of a sample, comprising:
scanning a first sample;
generating a beam map based on one or more failed charged particle beams of the scanning and one or more functional charged particle beams of the scanning;
developing a scanning strategy based on the generated beam map; and
scanning the first sample or a second sample according to the scanning strategy.
14. The method of clause 13, further comprising identifying the one or more failed charged particle beams by generating a grey level histogram for each charged particle beam of a plurality of charged particle beams associated with the scanning of the first sample.
15. The method of any one of clauses 13-14, further comprising identifying the one or more failed charged particle beams by determining any one of a sharpness or a resolution of an image generated as a result of a plurality of charged particle beams associated with the scanning of the first sample.
16. The method of clause 13, further comprising identifying the one or more failed charged particle beams by generating a grey level histogram for a plurality of images associated with a first charged particle beam to determine whether the first charge particle beam is failing.
17. The method of any one of clauses 13 or 16, further comprising identifying the one or more failed charged particle beams by determining any one of a sharpness or a resolution of a plurality of images associated with a first charged particle beam to determine whether the first charge particle beam is failing.
18. The method of any one of clauses 13-15, wherein the first sample has a predetermined pattern.
19. The method of any one of clauses 13-15 or 18, wherein generating the beam map excludes some identified one or more functional charged particle beams.
20. The method of any one of clauses 13-15 or 18-19, wherein the generated beam map is used to minimize overlapping of functional charged particle beams during scanning of the second sample.
21. The method of any one of clauses 13-15 or 18-20, wherein the scanning strategy comprises using the generated beam map to scan the second sample.
22. The method of any one of clauses 13-15 or 18-21, wherein the generated beam map is used to maximize scanning of the second sample.
23. The method of any one of clauses 13-15 or 18-22, wherein the scanning strategy comprises providing a charged particle beam to an area of the second sample corresponding to identified one or more failed charged particle beams.
24. The method of any one of clauses 13, 16, or 17, wherein the scanning strategy comprises providing a charged particle beam to an area of the first sample corresponding to identified one or more failed charged particle beams.
25. A method for optimizing scanning of a sample, comprising:
determining one or more beams of a multi-beam system that are failing;
determining one or more beams of the multi-beam system that are functioning;
generating a beam map based on the determination of one or more beams that are failing and the determination of one or more beams that are functioning; and
developing a scanning strategy of a sample based on the generated beam map.
26. The method of clause 25, wherein determining one or more beams of a multi-beam system that are failing comprises generating a grey level histogram for each beam of a plurality of beams associated with a scanning of a first sample.
27. The method of any one of clauses 25-26, wherein determining one or more beams of a multi-beam system that are failing comprises determining any one of a sharpness or a resolution of an image generated as a result of a plurality of beams associated with a scanning of a first sample.
28. The method of clause 25, wherein determining one or more beams of a multi-beam system that are failing comprises generating a grey level histogram for a plurality of images associated with a first beam to determine whether the first beam is failing.
29. The method of any one of clauses 25 or 28, wherein determining one or more beams of a multi-beam system that are failing comprises determining any one of a sharpness or a resolution of a plurality of images associated with a first beam to determine whether the first beam is failing.
30. The method of any one of clauses 25-27, wherein the sample has a predetermined pattern.
31. The method of any one of clauses 25-27 or 30, wherein generating the beam map excludes some of the one or more beams that are failing.
32. The method of any one of clauses 25-27 or 30-31, wherein the generated beam map is used to minimize overlapping of functional beams during scanning of the sample.
33. The method of any one of clauses 25-27 or 30-32, wherein the scanning strategy comprises using the generated beam map to scan the sample.
34. The method of any one of clauses 25-27 or 30-33, wherein the generated beam map is used to maximize scanning of the sample.
35. The method of any one of clauses 25-27 or 30-33, wherein the scanning strategy comprises providing a beam to an area of the sample corresponding to the determined one or more beams that are failing.
36. The method of any one of clauses 25, 28, or 29, wherein the scanning strategy comprises providing a beam to an area of the sample corresponding to the determined one or more beams that are failing.
37. A system for optimizing scanning of a sample, comprising a controller including circuitry configured to cause the system to perform:
providing a plurality of charged particle beams for scanning a first sample;
identifying one or more failed charged particle beams of the plurality of charged particle beams;
identifying one or more functional charged particle beams of the plurality of charged particle beams that scan the first sample;
generating a beam map based on the identified one or more failed charged particle beams and the identified one or more functional charged particle beams, wherein the generated beam map excludes the identified one or more failed charged particle beams; and
developing a scanning strategy based on the generated beam map for scanning the first sample or a second sample.
38. The system of clause 37, wherein identifying the one or more failed charged particle beams comprises generating a grey level histogram for each charged particle beam of the plurality of charged particle beams.
39. The system of any one of clauses 37-38, wherein identifying the one or more failed charged particle beams comprises determining any one of a sharpness or a resolution of an image generated as a result of the plurality of charged particle beams.
40. The system of clause 37, wherein identifying the one or more failed charged particle beams comprises generating a grey level histogram for a plurality of images associated with a first charged particle beam to determine whether the first charge particle beam is failing.
41. The system of any one of clauses 37 or 40, wherein identifying the one or more failed charged particle beams comprises determining any one of a sharpness or a resolution of a plurality of images associated with a first charged particle beam to determine whether the first charge particle beam is failing.
42. The system of any one of clauses 37-39, wherein the first sample has a predetermined pattern.
43. The system of any one of clauses 37-39 or 42, wherein generating the beam map excludes some of the identified one or more functional charged particle beams.
44. The system of any one of clauses 37-39 or 42-43, wherein the generated beam map is used to minimize overlapping of functional charged particle beams during scanning of the second sample.
45. The system of any one of clauses 37-39 or 42-44, wherein the scanning strategy comprises using the generated beam map to scan the second sample.
46. The system of any one of clauses 37-39 or 42-45, wherein the generated beam map is used to maximize scanning of the second sample.
47. The system of any one of clauses 37-39 or 42-46, wherein the scanning strategy comprises providing a charged particle beam to an area of the second sample corresponding to the identified one or more failed charged particle beams.
48. The system of any one of clauses 37, 40, or 41, wherein the scanning strategy comprises providing a charged particle beam to an area of the first sample corresponding to the identified one or more failed charged particle beams.
49. A system for optimizing scanning of a sample, comprising a controller including circuitry configured to cause the system to perform:
scanning a first sample;
generating a beam map based on one or more failed charged particle beams of the scanning and one or more functional charged particle beams of the scanning;
developing a scanning strategy based on the generated beam map; and
scanning the first sample or a second sample according to the scanning strategy.
50. The system of clause 49, further comprising identifying the one or more failed charged particle beams by generating a grey level histogram for each charged particle beam of a plurality of charged particle beams associated with the scanning of the first sample.
51. The system of any one of clauses 49-50, further comprising identifying the one or more failed charged particle beams by determining any one of a sharpness or a resolution of an image generated as a result of a plurality of charged particle beams associated with the scanning of the first sample.
52. The system of clause 49, further comprising identifying the one or more failed charged particle beams by generating a grey level histogram for a plurality of images associated with a first charged particle beam to determine whether the first charge particle beam is failing.
53. The system of any one of clauses 49 or 52, further comprising identifying the one or more failed charged particle beams by determining any one of a sharpness or a resolution of a plurality of images associated with a first charged particle beam to determine whether the first charge particle beam is failing.
54. The system of any one of clauses 49-51, wherein the first sample has a predetermined pattern.
55. The system of any one of clauses 49-51 or 54, wherein generating the beam map excludes some identified one or more functional charged particle beams.
56. The system of any one of clauses 49-51 or 54-55, wherein the generated beam map is used to minimize overlapping of functional charged particle beams during scanning of the second sample.
57. The system of any one of clauses 49-51 or 54-56, wherein the scanning strategy comprises using the generated beam map to scan the second sample.
58. The system of any one of clauses 49-51 or 54-57, wherein the generated beam map is used to maximize scanning of the second sample.
59. The system of any one of clauses 49-51 or 54-58, wherein the scanning strategy comprises providing a charged particle beam to an area of the second sample corresponding to identified one or more failed charged particle beams.
60. The system of any one of clauses 49, 52, or 53, wherein the scanning strategy comprises providing a charged particle beam to an area of the first sample corresponding to identified one or more failed charged particle beams.
61. A system for optimizing scanning of a sample, comprising a controller including circuitry configured to cause the system to perform:
determining one or more beams of a multi-beam system that are failing;
determining one or more beams of the multi-beam system that are functioning;
generating a beam map based on the determination of one or more beams that are failing and the determination of one or more beams that are functioning; and developing a scanning strategy of a sample based on the generated beam map.
62. The system of clause 61, wherein determining one or more beams of a multi-beam system that are failing comprises generating a grey level histogram for each beam of a plurality of beams associated with a scanning of a first sample.
63. The system of any one of clauses 61-62, wherein determining one or more beams of a multi-beam system that are failing comprises determining any one of a sharpness or a resolution of an image generated as a result of a plurality of beams associated with a scanning of a first sample.
64. The system of clause 61, wherein determining one or more beams of a multi-beam system that are failing comprises generating a grey level histogram for a plurality of images associated with a first beam to determine whether the first beam is failing.
65. The system of any one of clauses 61 or 64, wherein determining one or more beams of a multi-beam system that are failing comprises determining any one of a sharpness or a resolution of a plurality of images associated with a first beam to determine whether the first beam is failing.
66. The system of any one of clauses 61-63, wherein the sample has a predetermined pattern.
67. The system of any one of clauses 61-63 or 66, wherein generating the beam map excludes some of the one or more beams that are failing.
68. The system of any one of clauses 61-63 or 66-67, wherein the generated beam map is used to minimize overlapping of functional beams during scanning of the sample.
69. The system of any one of clauses 61-63 or 66-68, wherein the scanning strategy comprises using the generated beam map to scan the sample.
70. The system of any one of clauses 61-63 or 66-69, wherein the generated beam map is used to maximize scanning of the sample.
71. The system of any one of clauses 61-63 or 66-69, wherein the scanning strategy comprises providing a beam to an area of the sample corresponding to the determined one or more beams that are failing.
72. The system of any one of clauses 61, 64, or 65, wherein the scanning strategy comprises providing a beam to an area of the sample corresponding to the determined one or more beams that are failing.
73. A non-transitory computer readable medium that stores a set of instructions that is executable by at least one processor of a computing device to cause the computing device to perform a method for optimizing scanning of a sample, the method comprising:
providing a plurality of charged particle beams for scanning a first sample;
identifying one or more failed charged particle beams of the plurality of charged particle beams; identifying one or more functional charged particle beams of the plurality of charged particle beams that scan the first sample;
generating a beam map based on the identified one or more failed charged particle beams and the identified one or more functional charged particle beams, wherein the generated beam map excludes the identified one or more failed charged particle beams; and
developing a scanning strategy based on the generated beam map for scanning the first sample or a second sample.
74. The non-transitory computer readable medium of clause 73, wherein identifying the one or more failed charged particle beams comprises generating a grey level histogram for each charged particle beam of the plurality of charged particle beams.
75. The non-transitory computer readable medium of any one of clauses 73-74, wherein identifying the one or more failed charged particle beams comprises determining any one of a sharpness or a resolution of an image generated as a result of the plurality of charged particle beams.
76. The non-transitory computer readable medium of clause 73, wherein identifying the one or more failed charged particle beams comprises generating a grey level histogram for a plurality of images associated with a first charged particle beam to determine whether the first charge particle beam is failing.
77. The non-transitory computer readable medium of any one of clauses 73 or 76, wherein identifying the one or more failed charged particle beams comprises determining any one of a sharpness or a resolution of a plurality of images associated with a first charged particle beam to determine whether the first charge particle beam is failing.
78. The non-transitory computer readable medium of any one of clauses 73-75, wherein the first sample has a predetermined pattern.
79. The non-transitory computer readable medium of any one of clauses 73-75 or 78, wherein generating the beam map excludes some of the identified one or more functional charged particle beams.
80. The non-transitory computer readable medium of any one of clauses 73-75 or 78-79, wherein the generated beam map is used to minimize overlapping of functional charged particle beams during scanning of the second sample.
81. The non-transitory computer readable medium of any one of clauses 73-75 or 78-80, wherein the scanning strategy comprises using the generated beam map to scan the second sample.
82. The non-transitory computer readable medium of any one of clauses 73-75 or 78-81, wherein the generated beam map is used to maximize scanning of the second sample.
83. The non-transitory computer readable medium of any one of clauses 73-75 or 78-82, wherein the scanning strategy comprises providing a charged particle beam to an area of the second sample corresponding to the identified one or more failed charged particle beams.
84. The non-transitory computer readable medium of any one of clauses 73, 76, or 77, wherein the scanning strategy comprises providing a charged particle beam to an area of the first sample corresponding to the identified one or more failed charged particle beams.
85. A non-transitory computer readable medium that stores a set of instructions that is executable by at least one processor of a computing device to cause the computing device to perform a method for optimizing scanning of a sample, the method comprising:
scanning a first sample;
generating a beam map based on one or more failed charged particle beams of the scanning and one or more functional charged particle beams of the scanning;
developing a scanning strategy based on the generated beam map; and
scanning the first sample or a second sample according to the scanning strategy.
86. The non-transitory computer readable medium of clause 85, further comprising identifying the one or more failed charged particle beams by generating a grey level histogram for each charged particle beam of a plurality of charged particle beams associated with the scanning of the first sample.
87. The non-transitory computer readable medium of any one of clauses 85-86, further comprising identifying the one or more failed charged particle beams by determining any one of a sharpness or a resolution of an image generated as a result of a plurality of charged particle beams associated with the scanning of the first sample.
88. The non-transitory computer readable medium of clause 85, further comprising identifying the one or more failed charged particle beams by generating a grey level histogram for a plurality of images associated with a first charged particle beam to determine whether the first charge particle beam is failing.
89. The non-transitory computer readable medium of any one of clauses 85 or 88, further comprising identifying the one or more failed charged particle beams by determining any one of a sharpness or a resolution of a plurality of images associated with a first charged particle beam to determine whether the first charge particle beam is failing.
90. The non-transitory computer readable medium of any one of clauses 85-87, wherein the first sample has a predetermined pattern.
91. The non-transitory computer readable medium of any one of clauses 85-87 or 90, wherein generating the beam map excludes some identified one or more functional charged particle beams.
92. The non-transitory computer readable medium of any one of clauses 85-87 or 90-91, wherein the generated beam map is used to minimize overlapping of functional charged particle beams during scanning of the second sample.
93. The non-transitory computer readable medium of any one of clauses 85-87 or 90-92, wherein the scanning strategy comprises using the generated beam map to scan the second sample.
94. The non-transitory computer readable medium of any one of clauses 85-87 or 90-93, wherein the generated beam map is used to maximize scanning of the second sample.
95. The non-transitory computer readable medium of any one of clauses 85-87 or 90-94, wherein the scanning strategy comprises providing a charged particle beam to an area of the second sample corresponding to identified one or more failed charged particle beams.
96. The non-transitory computer readable medium of any one of clauses 85, 88, or 89, wherein the scanning strategy comprises providing a charged particle beam to an area of the first sample corresponding to identified one or more failed charged particle beams.
97. A non-transitory computer readable medium that stores a set of instructions that is executable by at least one processor of a computing device to cause the computing device to perform a method for optimizing scanning of a sample, the method comprising:
determining one or more beams of a multi-beam system that are failing;
determining one or more beams of the multi-beam system that are functioning;
generating a beam map based on the determination of one or more beams that are failing and the determination of one or more beams that are functioning; and
developing a scanning strategy of a sample based on the generated beam map.
98. The non-transitory computer readable medium of clause 97, wherein determining one or more beams of a multi-beam system that are failing comprises generating a grey level histogram for each beam of a plurality of beams associated with a scanning of a first sample.
99. The non-transitory computer readable medium of any one of clauses 97-98, wherein determining one or more beams of a multi-beam system that are failing comprises determining any one of a sharpness or a resolution of an image generated as a result of a plurality of beams associated with a scanning of a first sample.
100. The non-transitory computer readable medium of clause 97, wherein determining one or more beams of a multi-beam system that are failing comprises generating a grey level histogram for a plurality of images associated with a first beam to determine whether the first beam is failing.
101. The non-transitory computer readable medium of any one of clauses 97 or 100, wherein determining one or more beams of a multi-beam system that are failing comprises determining any one of a sharpness or a resolution of a plurality of images associated with a first beam to determine whether the first beam is failing.
102. The non-transitory computer readable medium of any one of clauses 97-99, wherein the sample has a predetermined pattern.
103. The non-transitory computer readable medium of any one of clauses 97-99 or 102, wherein generating the beam map excludes some of the one or more beams that are failing.
104. The non-transitory computer readable medium of any one of clauses 97-99 or 102-103, wherein the generated beam map is used to minimize overlapping of functional beams during scanning of the sample.
105. The non-transitory computer readable medium of any one of clauses 97-99 or 102-104, wherein the scanning strategy comprises using the generated beam map to scan the sample.
106. The non-transitory computer readable medium of any one of clauses 97-99 or 102-105, wherein the generated beam map is used to maximize scanning of the sample.
107. The non-transitory computer readable medium of any one of clauses 97-99 or 102-105, wherein the scanning strategy comprises providing a beam to an area of the sample corresponding to the determined one or more beams that are failing.
108. The non-transitory computer readable medium of any one of clauses 97, 100, or 101, wherein the scanning strategy comprises providing a beam to an area of the sample corresponding to the determined one or more beams that are failing.
109. The method of clause 18, further comprising identifying higher priority areas of the first sample and lower priority areas of the first sample based on the predetermined pattern.
110. The method of clause 109, wherein the scanning strategy comprises adjusting the generated beam map such that the one or more failed charged particle beams scan lower priority areas of the second sample and the one or more functional charged particle beams scan higher priority areas of the second sample.
111. The method of clause 30, further comprising identifying higher priority areas of the sample and lower priority areas of the sample based on the predetermined pattern.
112. The method of clause 111, wherein the scanning strategy comprises adjusting the generated beam map such that the one or more beams that are failing scan lower priority areas of the sample and the one or more beams that are functioning scan higher priority areas of the sample.
113. The system of clause 54, wherein the controller including circuitry is configured to cause the system to further perform identifying higher priority areas of the first sample and lower priority areas of the first sample based on the predetermined pattern.
114. The system of clause 113, wherein the scanning strategy comprises adjusting the generated beam map such that the one or more failed charged particle beams scan lower priority areas of the second sample and the one or more functional charged particle beams scan higher priority areas of the second sample.
115. The system of clause 60, wherein the controller including circuitry is configured to cause the system to further perform identifying higher priority areas of the sample and lower priority areas of the sample based on the predetermined pattern.
116. The system of clause 115, wherein the scanning strategy comprises adjusting the generated beam map such that the one or more beams that are failing scan lower priority areas of the sample and the one or more beams that are functioning scan higher priority areas of the sample.
117. The non-transitory computer readable medium of clause 90, wherein the set of instructions that is executable by at least one processor of a computing device to cause the computing device to further perform identifying higher priority areas of the first sample and lower priority areas of the first sample based on the predetermined pattern.
118. The non-transitory computer readable medium of clause 117, wherein the scanning strategy comprises adjusting the generated beam map such that the one or more failed charged particle beams scan lower priority areas of the second sample and the one or more functional charged particle beams scan higher priority areas of the second sample.
119. The non-transitory computer readable medium of clause 102, wherein the set of instructions that is executable by at least one processor of a computing device to cause the computing device to further perform identifying higher priority areas of the sample and lower priority areas of the sample based on the predetermined pattern.
120. The non-transitory computer readable medium of clause 119, wherein the scanning strategy comprises adjusting the generated beam map such that the one or more beams that are failing scan lower priority areas of the sample and the one or more beams that are functioning scan higher priority areas of the sample.

It will be appreciated that the embodiments of the present disclosure are not limited to the exact construction that has been described above and illustrated in the accompanying drawings, and that various modifications and changes may be made without departing from the scope thereof.

1. A system for optimizing scanning of a sample, comprising:
a controller including circuitry configured to cause the system to perform operations comprising:
providing a plurality of charged particle beams for scanning a first sample;
identifying one or more failed charged particle beams of the plurality of charged particle beams;
identifying one or more functional charged particle beams of the plurality of charged particle beams that scan the first sample;
generating a beam map based on the identified one or more failed charged particle beams and the identified one or more functional charged particle beams, wherein the generated beam map excludes the identified one or more failed charged particle beams; and
developing a scanning strategy based on the generated beam map for scanning the first sample or a second sample.

2. The system of claim 1, wherein identifying the one or more failed charged particle beams comprises generating a grey level histogram for each charged particle beam of the plurality of charged particle beams.

3. The system of claim 1, wherein identifying the one or more failed charged particle beams comprises determining any one of a sharpness or a resolution of an image generated as a result of the plurality of charged particle beams.

4. The system of claim 1, wherein identifying the one or more failed charged particle beams comprises generating a grey level histogram for a plurality of images associated with a first charged particle beam to determine whether the first charge particle beam is failing.

5. The system of claim 1, wherein identifying the one or more failed charged particle beams comprises determining any one of a sharpness or a resolution of a plurality of images associated with a first charged particle beam to determine whether the first charge particle beam is failing.

6. The system of claim 1, wherein the first sample has a predetermined pattern.

7. The system of claim 1, wherein generating the beam map excludes some of the identified one or more functional charged particle beams.

8. The system of claim 1, wherein the generated beam map is used to minimize overlapping of functional charged particle beams during scanning of the second sample.

9. The system of claim 1, wherein the scanning strategy comprises that the generated beam map is used to scan the second sample.

10. The system of claim 1, wherein the generated beam map is used to maximize scanning of the second sample.

11. The system of claim 1, wherein the scanning strategy comprises that a charged particle beam is provided to an area of the second sample corresponding to the identified one or more failed charged particle beams.

12. The system of claim 1, wherein the scanning strategy comprises that a charged particle beam is provided to an area of the first sample corresponding to the identified one or more failed charged particle beams.

13. A system for optimizing scanning of a sample, comprising:
a controller including circuitry configured to cause the system to perform operations comprising:
scanning a first sample;
generating a beam map based on one or more failed charged particle beams of the scanning and one or more functional charged particle beams of the scanning;
developing a scanning strategy based on the generated beam map; and
scanning the first sample or a second sample according to the scanning strategy.

14. The system of claim 13 further comprising identifying the one or more failed charged particle beams by generating a grey level histogram for each charged particle beam of a plurality of charged particle beams associated with the scanning of the first sample.

15. The system of claim 13, further comprising identifying the one or more failed charged particle beams by determining any one of a sharpness or a resolution of an image generated as a result of a plurality of charged particle beams associated with the scanning of the first sample.

16. A non-transitory computer readable medium that stores a set of instructions that is executable by at least one processor of a computing device to cause the computing device to perform operations for optimizing scanning of a sample, the operations comprising:
providing a plurality of charged particle beams for scanning a first sample;
identifying one or more failed charged particle beams of the plurality of charged particle beams;
identifying one or more functional charged particle beams of the plurality of charged particle beams that scan the first sample;
generating a beam map based on the identified one or more failed charged particle beams and the identified one or more functional charged particle beams, wherein the generated beam map excludes the identified one or more failed charged particle beams; and
developing a scanning strategy based on the generated beam map for scanning the first sample or a second sample.

17. The non-transitory computer readable medium of claim 16, wherein identifying the one or more failed charged particle beams comprises generating a grey level histogram for each charged particle beam of the plurality of charged particle beams.

18. The non-transitory computer readable medium of claim 16, wherein identifying the one or more failed charged particle beams comprises determining any one of a sharpness or a resolution of an image generated as a result of the plurality of charged particle beams.

19. The non-transitory computer readable medium of claim 16, wherein identifying the one or more failed charged particle beams comprises generating a grey level histogram for a plurality of images associated with a first charged particle beam to determine whether the first charge particle beam is failing.

20. The non-transitory computer readable medium of claim 16, wherein identifying the one or more failed charged particle beams comprises determining any one of a sharpness or a resolution of a plurality of images associated with a first charged particle beam to determine whether the first charge particle beam is failing.
